(19) United States
(12) Patent Application Publication
(10) Pub. No.: US 2025/0382722 A1
(43) Pub. Date: Dec. 18, 2025

(54) CHEMICAL VAPOR DEPOSITION PROCESS AND APPARATUS FOR DEPOSITION OF DIAMOND MATERIAL

(71) Applicant: Combine International, Incorporated, Troy, MI (US)

(72) Inventors: Shrikant Mehta, Bloomfield Hills, MI (US); Sanjeev Pareek, Englewood, CO (US); Alvarado Tarun, Troy, MI (US); Jean Laniog Tarun, Troy, MI (US)

(21) Appl. No.: 18/745,557

(22) Filed: Jun. 17, 2024

(51) Int. Cl. C30B 29/04; C30B 25/12; C30B 25/16

(52) U.S. Cl. CPC C30B 29/04; C30B 25/12; C30B 25/16

(57) ABSTRACT

Disclosed herein are methods for producing a diamond material, and preferably a single crystalline diamond material. Also disclosed is a DC chemical vapor deposition (DC-CVD) reactor for depositing diamond materials comprising a defect removal system incorporated within the CVD reactor, configured to remove carbonaceous outgrowth defects during a diamond deposition process, without interfering with or stopping the deposition process.

### TECHNICAL FIELD

The present invention relates generally to an apparatus and a process for producing a diamond material, preferably single crystal diamond (SCD), through a chemical vapor deposition process.

### BACKGROUND OF THE INVENTION

Presently there are two methods which have been developed and extensively used to manufacture high quality single diamond crystal (SCD) namely, high-pressure high-temperature (HPHT) synthesis and chemical vapor deposition (CVD). HPHT diamonds typically have yellowish and brownish tints because they are exposed to nitrogen while forming (this causes coloration of the diamond). However, diamonds grown by a CVD process are grown inside a reactor chamber and forms the crystal structure layer by layer, either homoepitaxially (i.e., using a diamond seed substrate) or heteroepitaxially (i.e., using a seed substrate of different composition). The CVD grown diamonds have comparable properties as those of natural diamond.

Owing to the flexibility of the CVD process, several reactor technologies have been developed using different methods of activating the gas phase of hydrogen and hydrocarbon, usually methane. The activation method generally utilizes thermal (hot filament), plasma (e.g., direct current (DC), radio frequency, microwave, etc.) or combustion flame (e.g., plasma torch) for energizing the reactant gases and disassociating the gas molecules. At present, microwave CVD (MW-CVD) is the most prominent CVD reactor technology, as it is an electrodeless technique. The plasma generated by electrodeless discharge is purer which makes it a suitable technique to produce high-purity SCDs.

The most widely-used CVD reactor for larger deposition area uses 915 MHz MW radiation. The deposition diameter can be increased to 150 mm. The prohibitive cost of procuring a 915 MHz reactor system capable of up to 120 kW of operating power delimits its further expansion for large-scale SCD manufacturing. Moreover, in high-power (120 kW) diamond growth conditions, proper resonant cavity design and effective microwave chamber coupling efficiency is required so that most of the injected MW power is used to dissociate the gases and not lost in heating-up the walls of the CVD chamber. Hence, to make the deposition area bigger by increasing the MW power and reducing the MW frequency, researchers need to tackle several processing challenges to ensure successful deposition of high-quality SCDs. These processing challenges are discussed in a U.S. Pat. No. 10,734,198B2. Grotjohn et al., (Diamond & Related Materials 14 (2005) 288-291), described the scaling behavior of MW-CVD from 25 mm to 150 mm diameter substrate holders for different reactor sizes. They showed that as the plasma discharge size increases, the discharge power density decreases significantly at a given pressure. No other CVD crystal growth processes are discussed. King et al., (Diamond & Related Materials 17 (2008) 520-524) also described scaling behavior of MW-CVDs up to 200 mm substrate holders on polycrystalline CVD diamond. The are no disclosures pertaining to single crystal CVD diamond growth.

The direct-current plasma-assisted CVD (DC-CVD) offer a promising alternative to MW-CVD. A number of non-patent documents [Lyu et al, Surf. Engg. Vol 35, (2019) and Lee et al, Thin Solid Films. Vol. 435 (2003) pp 89-94] and patent document [U.S. Pat. Nos. 9,534,315B2, 6,399,151B2] covering the DC discharge method have been published. Deposition areas were enlarged by using the diode-type electrode configuration [Diamond Rel. Mater. 19 (2010) 1168-1171] or the multiple hot-cathode geometry. Initial works using this setup were mostly focused on CVD of polycrystalline diamond (PCD) films and wafers. Lee et al., had reported scaling behavior of DC-CVD process for 100 mm to 200 mm substrate holders. Their worked showed that the 200 mm deposition system was a simple scaled-up version from the 100 mm deposition system, with no special plasma manipulation required. The chamber pressures specified in the prior art, as presented in US patent U.S. Pat. No. 6,399,151B2, are at least 100 Torr. Only polycrystalline CVD diamond was grown. Besides, there were no disclosures of how the higher DC plasma power densities affect the ratios of hydrocarbon-to-hydrogen and, optionally ratios of nitrogen- and oxygen-to-hydrogen, which affect the growth of DC-CVD diamond, particularly the DC-CVD growth process of SCD.

In order to enlarge the plasma diameter to 325 mm, higher power must be applied at a lower operating pressure below 100 Torr. At low pressure conditions, the most common challenge with fabricating high quality single crystal CVD diamond over a larger deposition area (i.e., 125 mm to 325 mm) is that such DC-CVD process has a very low growth rate and requires days and even weeks to obtain the desired thickness (i.e., 1 mm to 10 mm). This is because as the growth area is increased the power density decreases and thus decreasing the growth rate on each individual SCD seed. Additionally, a decrease in power density also leads to a decrease in the quality of grown single crystal CVD diamond material. The interrelated issues associated with increasing applied DC power at a lower deposition pressure to stabilize the plasma for days while maintaining the desired temperature to grow thick SCDs are not yet known in the art and needs to be addressed.

The instability of the DC plasma discharge causes unnecessary plasma warming and spontaneous arcing for a particular combination of process parameters, such as gas pressure, applied DC power and methane concentration [Diamond & Related Materials 12 (2003) 917-920]. The unnecessary plasma warming happens when cathode temperature is not within the desired temperature. Hence, cooling to the desired cathode temperature to prevent arcing, while at the same time cooling the anode to the appropriate SCD growth temperature when running at very high DC power must be achieved and maintained. In the conventional art [U.S. Pat. No. 6,399,151B2], a common approach to adjusting cathode and substrate holder temperatures involves mounting them onto a water-cooled electrode holder. A spacer is then inserted between the water-cooled cathode and the molybdenum cathode to allow control over temperature of the cathode. It is also known in the art that the cathode temperature needs to be maintained at a desired temperature to minimize formation of carbon granules and its carburization. Additionally, the bottom electrode, known as anode, needs to be maintained at a desired temperature for diamond growth to occur. Due to the substantial power magnitude required for ionizing process gases, especially in large area depositions with a reasonable growth rate, effective cooling of the electrodes is crucial. For longer growth durations, the spacer degrades and impedes the accurate control of temperature. There's no need to discontinue the growth process to replace the spacer. The present invention solves these challenges by using two process parameters, the temperature and volume of the cooling water. Furthermore, plasma stability is also affected by the proximity of the cathode to the plasma, apart from the substrate holder which serves as the anode. Hence, it is essential to design a DC-CVD system capable of in-situ adjustment of the distance between electrodes and to regulate their respective temperatures during the growth process. This capability is crucial to prevent arcs, stabilize the DC plasma, and ultimately prolong the growth process, especially in the production of thick SCD over a large deposition area.

One issue associated with conventional DC-CVD techniques is undesired arcing may occur during the DC-CVD growth process that develops into more severe plasma arcing, or “hard arcing,” within the reactor chamber. Hard arcs lead to melting of the substrate holder and burning of grown DC-CVD diamond materials. These hard arcs may sometimes extinguish the plasma, thereby prematurely interrupting the growth run and leading to thin SCD, which in turn results in reduced yields. The burnt materials from the hard arcs will also lead to multiple defects that will eventually lead to non-uniform plasma densities. Minimizing arcs is necessary.

Another inherent challenge to grow thick DC-CVD diamonds for hundreds of hours using a conventional DC-CVD apparatus is the unwanted deposits on the surface of the cathode. During the growth, these deposits may eventually fall down from the cathode directly onto the anode substrate holder below it. These falling deposits will later become a major source of unwanted outgrowths in the deposition area, leading to non-uniform plasma. Also, when an arc occurs during the growth, the deposits may be dislodged from the surface of the cathode and fall onto the growing CVD diamond material below it, leading to contamination and increased the impurity levels.

In all CVD diamond processes, a diamond seed or diamond material is used. There are instances where defects initially present on the surface of a diamond seed will evolve into unwanted carbonaceous outgrowths (see 74 in FIG. 4), disrupting the uniformity of the plasma during the growth process. Unwanted outgrowths emerge during the CVD growth process and constitute the primary cause of premature shutdown of the CVD growth process. This is because these carbonaceous outgrowths will grow faster than the CVD diamond material, eventually attracting and shrinking the plasma volume, which ultimately leads to uneven growth of the CVD diamond material and/or early shutdown. The upscaling strategy, involving the use of wider substrate holders and, consequently, a higher number of diamond seeds over extended growth times, also increases the probability of encountering these carbonaceous outgrowths that impede the growth of thick CVD diamonds. Other outgrowths, some having tentacle-like protrusions (see 76 in FIG. 4), are observed during the DC-CVD growth process due to the extended growth time periods required to obtain the desired thickness of DC-CVD diamond material, especially at low growth rates. Maintaining a stable plasma at high power densities over extended time periods across a large growth surface area of up to 75000 mm² (325 mm diameter) is not an easy feat. It requires not only precise control of the growth processes, but also in-situ removal of any unwanted outgrowths that might perturb the uniformity of the DC-plasma.

Based on the deficiencies described above, there remains a need for CVD apparatus and processes that are capable of growing high-quality single crystal DC-CVD material with high increased growth rates at low pressure levels. This is achieved by maintaining a high DC power densities along with increasing the methane concentration in the growth atmosphere. Additionally, there is a need for a growth process which is precisely controlled over extended amounts of time so as to increase scaling of high quality SCD material.

### SUMMARY

Disclosed herein are methods for producing a diamond material, and preferably a single crystalline diamond material. Also disclosed is a direct current chemical vapor deposition (DC-CVD) reactor for growing diamond materials which incorporates a defect removal system, configured to remove carbonaceous outgrowth defects during a diamond deposition process, without interfering with or stopping the process.

The diamond deposition method disclosed herein comprises a step of providing a seed material inside the CVD reactor and introducing process gases in the CVD reactor. The CVD reactor comprises a first electrode and a second electrode. The method further comprises the step of applying a DC voltage to the first electrode and second electrode, wherein the DC voltage is higher than 900 V, and generating a plasma between the first electrode and second electrode. The plasma generated has a power density of at least 1.0 W/mm² over a deposition area at least 12,000 mm². In further embodiments, the method further incorporates a step of removing unwanted defects from the diamond materials through a defect removal system, without interrupting the generated plasma in the CVD reactor.

Also disclosed herein is a chemical vapor deposition (CVD) reactor, which will be further described in detail in later sections. Further disclosed are diamond materials deposited through the methods and CVD reactors detailed herein.

### Selected Definitions and Nomenclature

As used herein, the term “defects” refers to carbonaceous outgrowths which occur during a CVD process of diamond materials. These carbonaceous outgrowths may be initiated on the surface of the diamond material being deposited, or on the substrate holder within the deposition chamber. The term “defects” is not intended to refer to crystallographic defects such as those due to doping, dislocations, grain boundaries, bulk defects, or other types of structural defects within the diamond crystal lattice.

As used herein, the term “DC-CVD” or “DC plasma CVD”, refer to a chemical vapor deposition (CVD) process wherein direct current (DC) is applied between two electrodes to generate a plasma within the CVD reactor. The term plasma-enhanced or “PECVD” can also interchangeably be used to refer to the same process. The direct current applied may be pulsed direct current.

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification encompass all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

As used herein, the terms “reduce,” “reduced,” “reducing,” “reduction,” “diminish,” and “decrease” (and grammatical variations thereof), describe, for example, a decrease of at least about 1%, 5%, 10%, 15%, 20%, 25%, 35%, 50%, 75%, 80%, 85%, 90%, 95%, 97%, 98%, 99%, or 100% as compared to a control. In particular embodiments, the reduction can result in no or essentially no (i.e., an insignificant amount, e.g., less than about 10% or even 5% or even 1%) detectable activity or amount.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the present disclosure.

The terms “over,” “under,” “between,” and “on” as used herein refer to a relative position of one component or material with respect to other components or materials where such physical relationships are noteworthy. For example in the context of materials, one material or material disposed over or under another may be directly in contact or may have one or more intervening materials. Moreover, one material disposed between two materials or materials may be directly in contact with the two layers or may have one or more intervening layers. In contrast, a first material or material “on” a second material or material is in direct contact with that second material/material. Similar distinctions are to be made in the context of component assemblies.

As used throughout this description, and in the claims, a list of items joined by the term “at least one of” or “one or more of” can mean any combination of the listed terms. For example, the phrase “at least one of X, Y or Z” can mean X; Y; Z; X and Y; X and Z; Y and Z; or X, Y and Z.

### BRIEF DESCRIPTION OF THE DRAWINGS

FIG. 1 is a block diagram detailing method steps of producing a diamond material in a chemical vapor deposition (CVD) reactor, in accordance with embodiments of the present invention.

FIG. 2 is a schematic diagram showing an example of the direct-current (DC) plasma-assisted CVD apparatus for growing CVD diamond material in accordance with embodiments of the present invention.

FIG. 3 is a schematic diagram of an electrically isolated defect removal system incorporated within the CVD reactor, in accordance with embodiments disclosed herein.

FIG. 4 is a cross-sectional view detailing movable, water-cooled and electrically isolated electrodes of the CVD reactor, in accordance with embodiments disclosed herein.

FIG. 5 are photographs showing examples of unwanted defects or outgrowths. The unwanted outgrowth depicts a coral-shaped or tentacle-like extensions of carbonaceous outgrowth emanating from the diamond seed surface or substrate holder during the CVD growth process.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Disclosed herein are methods for producing a diamond material, and preferably a single crystalline diamond material (SCD). Also disclosed is a direct-current chemical vapor deposition (DC-CVD) reactor for depositing diamond materials and a defect removal system incorporated within the CVD reactor, configured to remove carbonaceous outgrowth defects during a diamond deposition process, without interfering with or stopping the deposition process.

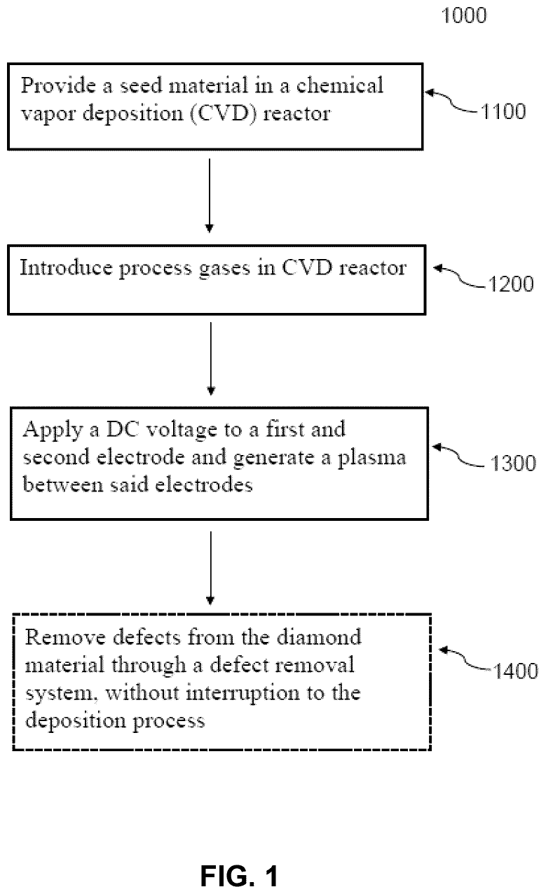

Seen in FIG. 1 is an embodiment for a method 1000 of producing a diamond material, in accordance with this invention. The method comprises a step 1100 of providing a seed material in a chemical vapor deposition reactor, and 1200 introducing process gases in the chemical vapor deposition reactor. The chemical vapor deposition reactor comprises a first electrode and a second electrode. The method further comprises the step 1300 of applying a DC voltage to the first electrode and second electrode, wherein the DC voltage is higher than 900V and generating a plasma between the first electrode and second electrode. The plasma generated has a power density of at least 1.0 W/mm² over a deposition area at least 12,000 mm². In further embodiments, the method further incorporates a step 1400 of removing defects from the diamond material through a defect removal system, without interrupting the generated plasma in the chemical vapor deposition reactor.

The various method steps depicted in FIG. 1 will now be discussed in further detail. In step 1100 a seed material is provided in the CVD reactor. The seed material, in one embodiment, is a single crystalline diamond (SCD) seed. SCD refers to any piece of diamond that is a single crystalline structure throughout and may come in various shapes and/or sizes. In some embodiments, the SCD seed can be sourced from an HPHT diamond, a CVD diamond, or a natural diamond. In some embodiments, the method step 1100 can further comprise a pre-cleaning step, wherein the SCD seed material is treated with hot acids, then ultrasonically cleaned with acetone before rinsing and drying. The seed material may comprise at least one or multiple SCD seeds placed onto the substrate holder of the CVD reactor.

The method also includes evacuating the DC-CVD reactor from 3 to 9 hours, or from 5 to 7 hours to achieve a vacuum pressure of less than 1.5 mTorr. The evacuation may be followed by a step of drizzling the reactor chamber between 30 minutes and 5 hours, alternatively between 3 and 4 hours. Drizzling, as used herein, refers to backfilling the reactor chamber with hydrogen gas, optionally nitrogen gas to chamber pressure between 2 and 30 Torr, or between 5 and 20 Torr. After drizzle, the method further includes a sub-step of pumping down the DC-CVD reactor chamber between 1 and 3 hours to reach a vacuum pressure of less than 1.5 mTorr.

In step 1200, process gases are introduced into the CVD reactor. The DC-CVD growth process may further comprise a step of prefilling of the DC-CVD reactor chamber with hydrogen gas to a pre-power gas chamber pressure between 1 to 10 Torr, or between 2 to 4 Torr. After prefilling the DC reactor chamber, DC voltage is applied across the electrodes to generate the DC plasma. In these embodiments, the steps of ramping up to the desired gas chamber pressure of DC reactor may occur concurrently with ramping up the DC power output. The desired growth gas chamber pressure is generally between 50 to 110 Torr, preferably 70 to 90 Torr depending on the diameter of the substrate holder. The substrate holder may have an area of ranging from 12,000 mm² to 75,000 mm², for a substrate holder with a circular cross-section and a diameter of ranging from 125 mm to 325 mm.

The process gases may comprise a hydrogen source gas and carbon source gas and optionally include an oxygen source gas, a nitrogen source gas and/or argon source gas. In certain embodiments, the carbon source gas may be methane. The flow rate of hydrogen gas can be between 300 sccm and 2000 sccm, and the flow rate of methane having a ratio of methane-to-hydrogen of 5% to 25%, oxygen-to-hydrogen of 0 to 1% and nitrogen-to-hydrogen of 0 to 0.005%. The method also includes maintaining the flow rate of the process gas at a desired total gas flow rate for an extended period of growth time. In certain embodiments, the total flow rate of process gases may be 3,000 sccm to 5,000 sccm. In other embodiments, the total flow rate of process gases may be 600 sccm to 1,500 sccm.

The CVD reactor has a first electrode and a second electrode. These refer to the anode and cathode of the reactor. For purposes of embodiments disclosed herein, the first electrode will refer to the anode in the reactor, and the second electrode will refer to the cathode. In step 1300 a DC voltage is applied across the anode and cathode to generate a plasma between the two electrodes. In some embodiments, the DC plasma has a power density of between 1.0 W/mm² and 6.0 W/mm², 1.2 W/mm² and 6.0 W/mm², or 2 W/mm² and 5 W/mm², or 3 W/mm² and 4 W/mm², or any smaller range or single value there between.

In certain some embodiments, the step of applying DC power to the electrodes further comprises heating the second electrode to a temperature of between 850° C. and 1200° C. The method further includes maintaining the SCD seed at a temperature of between 900° C. and 1100° C. and maintaining the cathode temperature of between 850° C. and 1200° C. In embodiments, the step of maintaining the SCD seed and cathode temperature comprises maintaining a predetermined plasma density within 5% for at least 72 hours to 1000 hours. In one embodiment, the diamond material produced through process steps disclosed herein is single crystalline diamond having a thickness of between 1.0 mm to 10 mm.

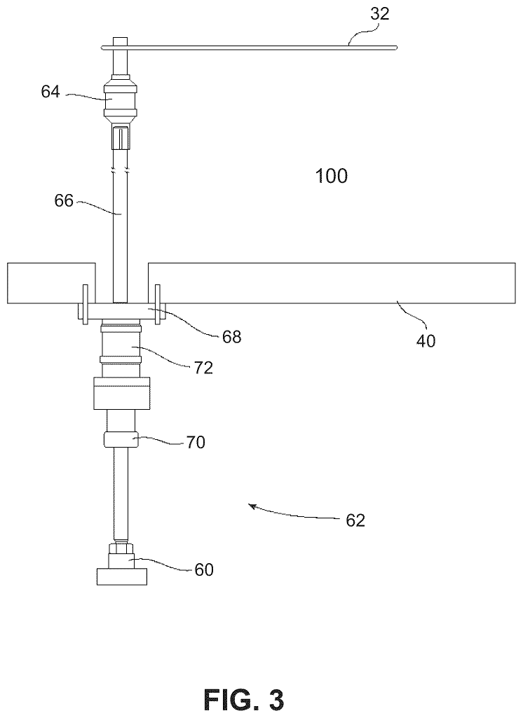

The method further includes step 1400 of removing defects from the diamond material and/or substrate holder within the reactor by use of a defect removal system, shown in FIG. 3 and discussed in more detail in later sections of this disclosure. The step of removing defects from the diamond material comprises the removal of carbonaceous outgrowth which typically occur during the deposition process, primarily due to graphitization.

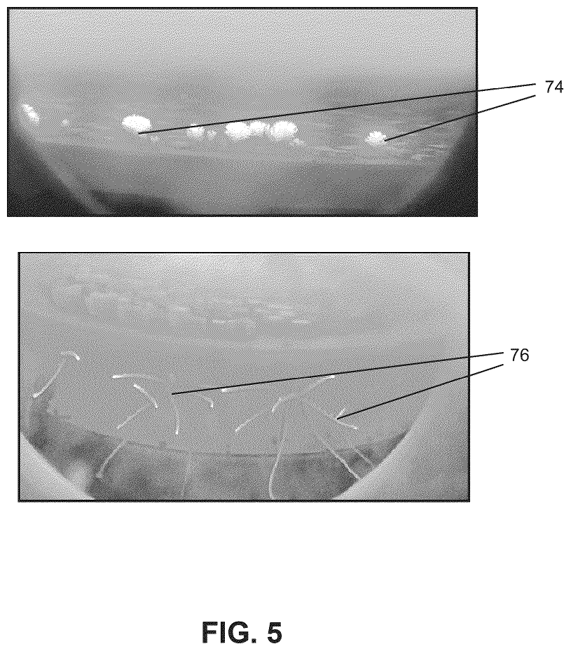

Carbonaceous defects or outgrowths are a persistent problem in diamond synthesis in CVD reactors. These carbonaceous outgrowths impede growth of sufficiently thick DC-CVD diamond material. This is because during the course of the DC-CVD diamond material growth, the coral-shaped outgrowths 74, shown in FIG. 5, grow faster than the DC-CVD diamond material and eventually distort the DC plasma uniformity which ultimately results in uneven growth and/or extinguish the DC plasma. The probability of these coral-shaped outgrowths 74, occurring in larger deposition areas is significantly higher compared to a smaller deposition area. This higher probability is primarily due to the increase in the number of SCD seeds associated with a larger deposition area. Therefore, the careful control over the onset of these carbonaceous outgrowths 74, 76, via the step of removing the unwanted outgrowths using the defect removal system is effective in promoting DC plasma uniformity and/or preventing the DC plasma from extinguishing. Other outgrowths, depicted in FIG. 5 as tentacle-like protrusions 76, are observed in DC-CVD process due to the extended growth time periods required to obtain the desired thickness of DC-CVD diamond material.

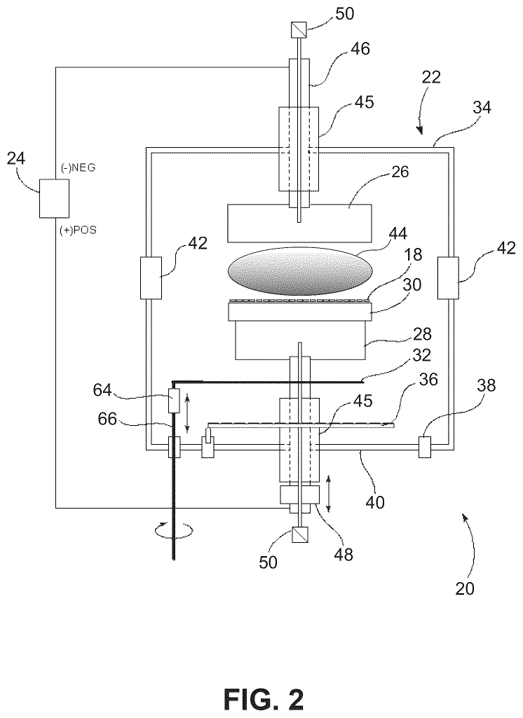

The step of removing outgrowths comprise of gently moving a sweeper mechanism 32 (shown in FIGS. 2 and 3), and allowing it to come into electrical contact with the electrically grounded DC reactor chamber 34. This sub-step is performed to remove possible build-up of electrical charges accumulating on the sweeper mechanism. The height of the sweeper mechanism 32 can adjusted by holding and pushing a control mechanism 60, of the defect removal system 62 to raise it from a resting position at the bottom of the DC reactor chamber, to a raised position, just above the SCD seed material on the substrate holder and in proximity to the specific SCD seed with carbonaceous outgrowths 74. The sweeper mechanism is moved horizontally to dislodge the outgrowths 74, without making physical contact with the growing DC-CVD diamond material directly on top of the seed material. One or more sweeper mechanisms can be present in a CVD reactor depending on the size of the chamber, location of the diamond seeds and their accessibility.

Also disclosed herein is a chemical vapor deposition (CVD) reactor 20, an embodiment of which is shown in FIG. 2. In this particular embodiment, the reactor is a DC plasma CVD reactor (also referred to as a DC-CVD reactor). The DC-CVD reactor 20 includes a DC reactor chamber 22, a DC power supply 24, a first electrode, also referred to as an anode 28, a second electrode, also referred to as a cathode 26, and a substrate holder 30. The reactor further comprises a defect removal system 62 (shown in FIGS. 2 and 3). The defect removal system 62, comprises a sweeper rod mechanism 32 and a control mechanism 60. The sweeper rod mechanism 32 configured to be moveable within the chamber of the CVD reactor, while the control mechanism 60 (seen in FIG. 3) configured to be operable outside the chamber of the CVD reactor.

The DC-CVD reactor chamber 22, generally includes reactor chamber walls 34, wherein a gas inlet 36, and a gas outlet 38, are installed. The cathode 26, and anode 28, are each electrically connected to the DC power supply 24. The cathode 26, anode 28, substrate holder 30, and sweeper rod 32, are positioned within the DC reactor chamber 22. Generally, the substrate holder 30, is placed on top of the anode 28. The sweeper rod 32, is positioned just above the chamber baseplate 40, when not in use. The sweeper mechanism, also referred to as a sweeper rod 32, due to its rod-like configuration, may move vertically, laterally and rotationally between the substrate holder 30, and the cathode 26, when needed to knock-off unwanted carbonaceous defects on the SCD seed 18, during the DC-CVD growth process.

The DC-CVD reactor 20, comprises a water-cooled DC chamber walls 34. In some embodiments, the gas inlet 36, is a ring-typed in configuration and is positioned just above the chamber baseplate 40, but below the substrate holder 30, and/or anode 28. The DC reactor chamber 22, includes a gas outlet 38, that is connected to a control valve to continuously regulate and maintain a predetermined pressure inside the DC reactor chamber between 50 Torr to 110 Torr during diamond growth. The DC-CVD reactor chamber 22, may further comprise of one or more viewing windows 42. In some embodiments, one or more of the viewing windows 42, may comprise of quartz. The viewing windows 42, facilitates the temperature monitoring of the growing DC-CVD diamond material over the SCD seeds 18, using an optical pyrometer. The viewing windows 42, also facilitates the measurement of the optical emission spectra.

When a DC voltage from the DC power supply 24, is applied across the first and second electrodes in the DC-CVD reactor chamber that is filled with process gases, it creates an electric field that accelerates the free electrons present in the chamber. These energetic free electrons inelastically collide with the reactant gases, causing complex chemical reactions that lead to breakdown of the process gas molecules and produce a glow discharge, known as DC plasma. The uniform DC plasma 44, formed between the anode 28, and the cathode 26, is situated in proximity to a growth surface of an SCD seed material 18, where DC-CVD diamond materials are grown. The voltage of the DC power supply 24, is at least 900V. In some embodiments, the DC power supply is between 1000V to 1200V. This allows for achieving a uniform and high DC power density, thereby promoting higher growth rates and better DC-CVD diamond quality. The output of DC power supply 24, may be maintained to deliver a power density of at least 1.0 W/mm², 2.0 W/mm², 3.0 W/mm², and no more than 6.0 W/mm², 5.0 W/mm², or 4.0 W/mm², wherein the DC-plasma 44, is at a gas chamber pressure of between 50 Torr and 110 Torr, wherein a deposition area is 12000 mm² to 75000 mm². Assuming all the applied DC power is absorbed, power density is calculated by dividing the output power of DC power supply 24, by the growth surface area of substrate holder 30. The growth surface area is calculated from the diameter of 30. The DC power supply 24, operates in power-regulation mode, wherein the regulator ensures that the DC output power remains within 3% of the rated or setpoint value, irrespective of the current consumed and/or discharge voltage variations resulting from changes in the impedance of the DC plasma 44. In the present invention, a DC power supply 24, capable of delivering up to 1200 V, is utilized in order to obtain uniform DC plasma with high power density.

The cathode 26, and the anode 28, define an inter-electrode distance. In some embodiments, the anode 28, and substrate holder 30, may be formed in a single anode-substrate unit. The anode-substrate unit is moveable such that the inter-electrode distance may be varied throughout the growth process. The cathode 26, and anode 28, are referred to collectively herein as “the electrodes” 26, 28. The DC reactor chamber 20 may be equipped with high melting point (>2500° C.) refractory metal electrodes 26, 28, which may comprise of molybdenum or tungsten. The cathode 26, and anode 28, may be electrically isolated from the DC reactor chamber 20 using a ceramic break 45. The ceramic break 45, is used to provide electrical isolation of the DC biased output terminal of the DC power supply 24 to the electrically grounded DC reactor 20. The anode 28, may not be electrically isolated to the grounded DC reactor 20. The cathode 26, and/or the anode 28, may be water-cooled. In certain embodiments, the cathode 26, and anode 28, both have a circular cross-section with a diameter between 125 mm to 325 mm.

In some embodiments, the DC-CVD reactor 20, further comprises of electrode-mounting post assembly 46. The electrode-mounting post assembly 46, may be affixed to a motorized stage 48, designed to stabilize the DC plasma 44, by varying the inter-electrode spacing during growth of the SCD seed 18. The most stable and uniform high plasma density may be obtained by varying the inter-electrode distance between 40 mm to 100 mm depending on the diameter of the substrate holder 30.

As shown in FIG. 2, one embodiment of the invention is the independent control mechanism for regulating the temperature of both the cathode 26, and the anode 28, during the growth process. This control is achieved through manipulation of the inlet temperature and flow rates of the cooling water for each component. The flow rate is adjusted by a flow meter 50. Desired temperature of the cathode during the growth process is obtained by simply adjusting the volume and/or temperature of the inlet cooling water to minimize formation of carbon granules and carburization of the cathode.

To facilitate the growth DC-CVD diamond material from SCD seed 18, the temperature of the cathode 26, anode 28, and/or substrate holder 30, is independently cooled externally outside the DC reactor chamber wall 34, during the growth process using the flow meter 50. The present invention may also incorporate a gradual adjustment of DC power output and gas chamber pressure at times during the growth process to regulate the temperature of the growing DC-CVD diamond material on top of the SCD seeds 18. The substrate holder 30, which may be a disc type substrate holder, may comprise molybdenum or tungsten and may be placed on top of the anode 28.

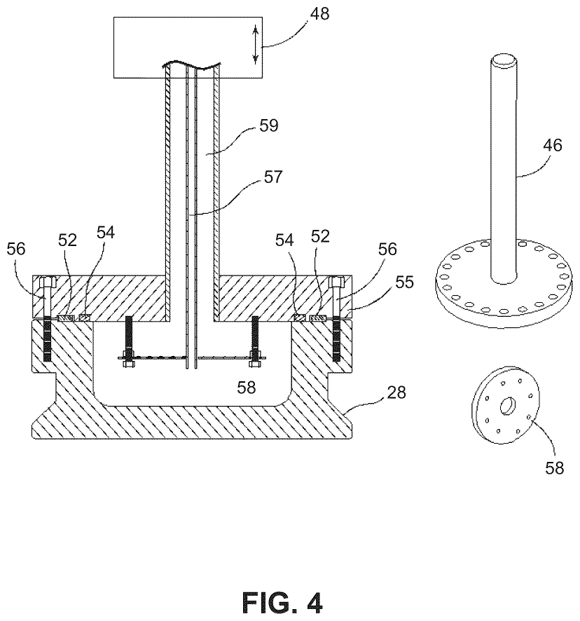

FIG. 4 shows the schematic diagram of the anode 28, in FIG. 1 that is preferably composed of stainless steel, molybdenum, or copper. The cooling structure of the cathode 26, is similar to that of the anode 28. The electrodes 26, 28, may be sealed using copper gaskets 52, O-rings 54, by threading screws 56, onto a flange. In some embodiments, the flange is a metal flange, or, more specifically, a stainless-steel metal flange 55. The flange 55, may include a welded hollow mounting post assembly 46, which may comprise stainless steel. The mounting post assembly 46, may also have a water inlet hollow post 57, for injecting cold water and a water outlet 59, for discharging hot water. The electrode mounting post assembly 46, may comprise a disc-plate 58, which may comprise stainless steel. The disc-plate 58, is attached to the mounting post assembly to help guide the flow of the cooling water from a center of a well towards an edge of the well and on to the water outlet. The temperature of the inlet cooling water is typically between 18° C. and 25° C. Depending on the applied DC power density and temperature of the inlet cooling water, a flow rate of at least 1.0 L/min and no more than 50.0 L/min is used.

As shown in FIGS. 2 and 3, the DC-CVD reactor 20, includes a sweeper rod 32. The sweeper rod 32, is generally configured to knock off or remove unwanted defects or outgrowths that may arise on the surface of the DC-CVD diamond material and/or substrate holder 30, throughout the DC-CVD growth process. In some embodiments, the sweeper rod 32, is electrically insulated from the grounded DC reactor 20 and the output terminals of the DC power supply 24. A control mechanism 60, which can be a knob assembly, may also be integrated into a linear and rotational actuator to enable motorized sweeping motions.

The defect removal system 62, shown in FIG. 3, for removing outgrowths that arise during the production of a DC-CVD diamond material is further provided. The defect removal system 62, comprises a sweeper rod 32, mounted to a ceramic break 64 to electrically isolate it from the support metal rod 66. The support rod 66, may comprise a refractory metal or stainless steel. The defect removal system 62, may also include a mounting flange 68, and a knob 70, to create vacuum seal when mounting the defect removal assembly 62, into a DC reactor chamber 20. The defect removal system 62, may be electrically isolated from any or all other elements of a DC-CVD reactor 20. The defect removal system further comprises a control mechanism 60, which is operable outside the CVD chamber, to control movements of the sweeper rod 32, within the chamber.

Electrical isolation of the sweeper rod 32, prevents electrical discharge from the electrodes 26, 28, directly to the sweeper rod 32. This measure minimizes overheating of the sweeper rod 32 and avoids disruption of the DC plasma's 44 uniformity. Electrically isolating the defect removal system 62, and/or support rod 32, will also prevent direct arcing into the sweeper rod 32. Overheating the sweeper rod 32, may cause the bending of the sweeper rod 32. In some embodiments, the DC-CVD reactor 20 comprises a plurality of the defect removal system 62. In some DC-CVD reactors, it is necessary to implement cooling methods into the sweeper rod 32. The ceramic break 72, is to provide electrical isolation of the metallic support rod 66, to the chamber baseplate 40.

Also disclosed are diamond materials deposited and/or grown through the DC-CVD methods described in various embodiments herein. The diamond materials grown according to said methods have properties which are applicable or tailored for use in optical, thermal, computing, sensing, mechanical or jewelry applications.

In one embodiment, the diamond materials produced in accordance with embodiments disclosed herein are grown with processes gases which contain a nitrogen content of no more than 3.0 ppm. In other embodiments, the processes gases contain at least 15 ppm but not more than 50 ppm of nitrogen.

In certain embodiments, the diamond materials are single crystal diamond (SCD) which can have a thickness of at least 1.0 mm, in addition to having a color which is near colorless or brown-colored as viewed under microscope. In other embodiments, the diamond materials deposited have a thickness of at least 2.0 mm, or at least 3.0 mm, or at least 4.0 mm, or at least 5.0 mm, or at least 6 mm, or at least 7.0 mm, or at least 8.0 mm, or at least 9.0 mm, or at least 10.0 mm.

In certain embodiments, the diamond material exhibits a color grade of L, M to fancy yellow after HPHT treatment, if cut into a carat round brilliant gemstone. In other embodiments, the diamond material exhibits a color grade of I, J, K after HPHT treatment, if cut into a carat round brilliant gemstone. In further embodiments, if cut into a carat round brilliant gemstone, the diamond material exhibits a near colorless grade after HPHT treatment

### Example 1

Growth of (100)-Oriented DC-CVD diamond material on SCD seed using 152 mm diameter electrodes in the DC-CVD System.

A 40-kW DC-CVD system with a 152 mm diameter disc-type substrate holder was used for SCD growth. Polished (100)-oriented, 6 mm×6 mm×0.5 mm SCD seeds, grown from either HPHT or CVD, were inspected and sorted using a low magnification microscope with up to 10× total magnification and were equipped with linear polarizing accessories. SCD seeds with minimal defects and low stress levels, as measured from cross-polarized microscope, underwent a cleaning process with hot acids followed by ultrasonic cleaning with acetone before being rinsed and dried. The SCD seeds were set 1 mm to 2 mm apart from each other onto the 152 mm diameter molybdenum substrate holder placed on top of the electrically insulated anode-substrate unit. The reactor chamber was evacuated for 6 hours and then drizzled (backfilled to a pressure of up to 10 Torr with hydrogen) for 2 hours and then pumped down to a vacuum pressure of less than 1.5 mTorr for 2 hours. The chamber was backfilled until it reaches a stable pressure of 3.0 Torr before applying the DC power to ignite the plasma. The inter-electrode distance was initially set at 55 mm. The power and pressure were then slowly ramped until it reaches a stable pressure of 90 Torr at a flow rate of up to 550 sccm with hydrogen having 7N purity. DC power of up to 35 KW (for a power density of 1.92 W/mm²) was applied to form DC plasma across the electrodes, and the plasma covered the whole substrate holder surface. The seed temperature was kept at 1050+50° C., as measured by an optical pyrometer using the reactor windows. After stabilizing the plasma at 60 mm inter-electrode spacing for up to 5 hours, a carbon source gas, which may comprise methane (CH₄) and/or carbon dioxide (CO₂), was introduced into the chamber followed by a nitrogen source gas (molecular nitrogen). The total gas flow rate was maintained up to 600 sccm, while the CH₄/H₂ gas ratio used is up to 7.0%. The addition of 3.8 ppm of molecular nitrogen and 1900 ppm of molecular oxygen to the process gas increased the growth rate and quality of the crystals. Growth was carried out for at least 450 hours and very light brown single crystal DC-CVD diamond of 4.5 mm in thickness was formed. During the entire growth process, inter-electrode spacing was fixed at 60 mm. At the end of the growth run, the gas flows were terminated, and the system was powered down to cool down the crystals. The reactor chamber was then evacuated to remove all the gases and then vented out to atmospheric pressure. Additional experiment was conducted by changing the molecular nitrogen to 27 ppm and 2250 ppm molecular oxygen increased the growth rate by 5 micron/hr. However, a higher percentage of molecular nitrogen resulted in darker brown-colored as-grown single crystal DC-CVD. Changing the molecular nitrogen to 1.5 ppm and 1900 ppm molecular oxygen to the process gas decreased the growth rate. A lower percentage of molecular nitrogen led to nearly colorless as-grown single crystal DC-CVD, thereby improving the purity of the crystals compared to a higher percentage of molecular nitrogen.

### Example 2

Growth of (100)-Oriented DC-CVD diamond material on SCD Seed using 205 mm diameter electrodes in the DC-CVD System.

A 60-kW DC-CVD system with a 205 mm diameter disc-type substrate holder was used for SCD growth. Polished (100)-oriented SCD seeds, previously produced by either HPHT or CVD and having thicknesses of 0.5 mm, were inspected, and sorted using a low magnification microscope with up to 10× total magnification and equipped with linear polarizing accessories. SCD seeds with minimal defects and low stress levels, as measured from a cross-polarized microscope, underwent a cleaning process with hot acids followed by ultrasonic cleaning with acetone before being rinsed and dried. The seeds were loaded 1 mm to 2 mm apart onto the 205 mm molybdenum substrate holder on top of the anode substrate which was electrically insulated. The reactor was evacuated to a pressure of less than 1.5 mTorr for 6 hours, drizzled with hydrogen and then backfilled to a pressure of up to 75 Torr at a flow rate of up to 550 sccm with H₂ having 7N purity. The inter-electrode spacing was initially set at 60 mm. Power of up to 60 KW (power density of 1.82 W/mm²) was applied in order to form the DC plasma across the electrodes, and cover the whole substrate holder surface with plasma. The seed temperature was kept at 1050+50° C., as measured by an optical pyrometer. After stabilizing the plasma at 70 mm inter-electrode spacing for up to 5 hours, a carbon gas source, CH₄ and carbon dioxide (CO₂) were introduced into the chamber followed by a nitrogen gas source. The total gas flow rate was maintained up to 600 sccm, while the CH₄/H₂ gas ratio used was up to 13.0%. Addition of 10 ppm of molecular nitrogen and 2100 ppm of molecular oxygen to the process gas increased the growth rate and quality of the crystals. Growth was carried out for at least 500 hours and a single crystal DC-CVD diamond of 4.0 mm in thickness and light brown in color was formed. During the entire growth process, the inter-electrode distance was varied between 65 mm and 75 mm. Additional experiment was conducted by changing the molecular nitrogen to 33 ppm and 2100 ppm molecular oxygen increased the growth rate by 2.5 micron/hr. However, a higher percentage of molecular nitrogen also resulted in brown-colored as-grown single crystal DC-CVD.

### Example 3

Growth of (100)-Oriented DC-CVD diamond material on SCD Seed using 325 mm diameter electrodes in the DC-CVD System.

A 120-kW DC-CVD system with 325 mm diameter disc-type substrate holder was used for SCD growth. Polished (100)-oriented SCD seeds, produced by CVD and having thicknesses of 0.5 mm, were inspected and sorted using a low magnification microscope with up to 10× total magnification. SCD seeds with minimal defects and low stress levels, as measured from cross-polarized microscope, underwent cleaning process with hot acids followed by ultrasonic cleaning with acetone before being rinsed and dried. The SCD seeds were loaded 1-2 mm apart onto the 325 mm molybdenum substrate holder on top of the anode substrate which was electrically insulated. The reactor was evacuated to for 6 hours and then backfilled to a pressure of up to 75 Torr at a flow rate of up to 500 sccm with H₂ having 7N purity. A power density of up to 100 KW (corresponding to a power density of 1.37 W/mm²) was applied in order to form stable DC plasma across the electrodes, and cover the whole substrate holder surface with DC plasma. The seed temperature was kept at 1050+50° C., as measured by an optical pyrometer. After stabilizing the plasma at an 80 mm inter-electrode distance for up to 9 hours, a carbon gas source, which was methane (CH₄) and carbon dioxide (CO₂), was introduced into the DC reactor chamber followed by a nitrogen gas source, which was molecular nitrogen. The total gas flow rate was maintained up to 600 sccm, while the CH₄/H₂ gas ratio used is up to 16.5%. Addition of 3 ppm of molecular nitrogen and 2000 ppm of molecular oxygen to the process gas increased the growth rate and quality of the crystals. Growth was carried out for at least 550 hours and single crystal DC-CVD near colorless diamond of 4.5 mm in thickness was formed. Another experiment was conducted by increasing the molecular nitrogen to 12 ppm while maintaining the 2000 ppm molecular oxygen increased the growth rate by 1.0 micron/hr. This time, the growth was carried out for 500 hours and light brown single crystal DC-CVD diamond of 4.1 mm in thickness was formed. Additional experiment was conducted by changing the molecular nitrogen to 42 ppm and 2600 ppm molecular oxygen increased the growth rate by 4.0 micron/hr. However, a higher percentage of molecular nitrogen also resulted in as-grown dark brown colored single crystal DC-CVD. During the entire growth process, inter-electrode spacing was varied between 65 mm and 80 mm.

### Example 4

Growth of (100)-Oriented DC-CVD diamond material on SCD Seed using 125 mm diameter electrodes in the DC-CVD System.

A 20-kW DC-CVD system with a 125 mm diameter disc-type substrate holder was used for SCD growth. Polished (100)-oriented SCD seeds, produced by CVD and having a thickness of 0.5 mm, were inspected and sorted using a low magnification microscope with up to 10× total magnification. SCD seeds with minimal defects and low stress levels, as measured from a cross-polarized microscope, underwent a cleaning process with hot acids followed by ultrasonic cleaning with acetone before being rinsed and dried. The SCD seeds were loaded 1 mm to 2 mm apart onto a 125 mm molybdenum substrate holder on top of the anode substrate which was electrically insulated. The reactor was evacuated for 6 hours and then backfilled to a pressure of up to 95 Torr at a flow rate of up to 500 sccm with H₂ having 7N purity. DC power of up to 20 kW (corresponding to a power density of 1.58 W/mm²) was applied to form stable plasma across the electrodes and covered the whole substrate holder surface with plasma. The seed temperature was kept at 1050+50° C., as measured by an optical pyrometer. After stabilizing the plasma at a 50 mm inter-electrode distance for up to 5 hours, a carbon gas source, which includes methane (CH₄) and carbon dioxide (CO₂), was introduced into the DC reactor chamber followed by a nitrogen gas source, which included molecular nitrogen. The total gas flow rate was maintained up to 533 sccm, while the CH₄/H₂ gas ratio used was up to 5.5%. Addition of 5 ppm of molecular nitrogen and 3300 ppm of molecular oxygen to the process gas increased the growth rate and quality of the crystals. Growth was carried out for at least 500 hours and light brown single crystal DC-CVD diamond of 4.5 mm in thickness was formed. An additional experiment was conducted by changing the molecular nitrogen to 20 ppm and 3300 ppm molecular oxygen which increased the growth rate by 2.5 micron/hr. However, a higher percentage of molecular nitrogen also resulted in as-grown dark brown colored SCD DC-CVD. During the entire growth process, inter-electrode spacing was fixed 50 mm.

The methane-to-hydrogen and nitrogen-to-hydrogen optimal flow rate ratio at particular power densities was found to be dependent on the deposition diameter of the substrate holder, wherein the growth surface area is between 12000 mm² to 75000 mm² (corresponding to substrate holder diameters between 125 mm to 325 mm) and also on the quality of the DC plasma-assisted CVD SCD being produced. Generally, the optimal ratio increased with increasing deposition diameter at a fixed power density. The color of an as-grown round-cut 1-carat DC-CVD SCD varies from near colorless to light brown to dark brown as the concentration of nitrogen in the process gas increases from zero to 50 ppm. The as-grown color of DC-CVD SCDs was also found to be influenced by growth deposition temperature. Lighter colored DC-CVD SCDs were observed when the deposition temperature was held at 1100° C. when compared to DC-CVD SCDs grown at a temperature of 900° C. The HPHT treatment is carried out in a temperature range of 1800° C. to 2300° C. under diamond-stabilizing pressure for a duration ranging from 2 to 10 minutes

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

1. A method of producing a diamond material, comprising:
providing a seed material in a chemical vapor deposition reactor;
introducing process gases in the chemical vapor deposition reactor;
wherein the chemical vapor deposition reactor comprises:
a first electrode;
a second electrode;
applying a DC voltage across the first electrode and second electrode, wherein the DC voltage is higher than 900V;
generating a plasma between the first electrode and second electrode, wherein the plasma has a power density of at least 1.0 W/mm² and a deposition area at least 120,000 mm².

2. The method of claim 1, further comprising removing defects from the diamond material through a defect removal system, without stopping the deposition process.

3. The method of claim 1, wherein the DC voltage applied is about 1000V to 12000V.

4. The method of claim 1, wherein the plasma generated has a power density of about 1.2 W/mm² to 6.0 W/mm².

5. The method of claim 1, wherein the deposition area is about 12,000 mm² to 75,000 mm², and wherein the reactor chamber pressure is about 50 Torr and 110 Torr.

6. The method of claim 1, wherein the process gases comprise a hydrogen source gas and a carbon source gas, wherein the hydrogen source gas has a flow rate of about 300 and 2000 sccm, and wherein the carbon source gas is methane.

7. The method of claim 6, wherein the process gases further comprise an oxygen source gas, a nitrogen source gas, and argon source gas, wherein the concentration by volume of oxygen-to-hydrogen is in a range 0 to 1% and nitrogen-to-hydrogen is in a range 0 to 0.005% and argon-to-hydrogen is in a range 0 to 1%.

8. The method of claim 1, wherein the plasma's power density of at least 1.0 W/mm² is maintained by varying the distance between the first electrode and second electrode from 40 mm to 100 mm.

9. The method of claim 1, wherein the diamond material is a single crystalline diamond having a thickness of about 1.0 mm to 10.0 mm.

10. A diamond material, produced according to the method of claim 1.

11. The method of claim 1, wherein the second electrode's temperature is maintained between 850° C. and 1200° C. and the seed material's temperature is maintained between 900° C. and 1100° C., during the diamond material production process.

12. A direct current chemical vapor deposition (DC-CVD) reactor, comprising:
a first electrode and a second electrode within a reactor chamber;
a substrate holder;
a gas inlet and gas outlet;
a DC power source electrically connected to the first and second electrode; and
a defect removal system for removing carbonaceous defects during a deposition process.

13. The direct current chemical vapor deposition (DC-CVD) reactor of claim 12, wherein the defect removal system comprises:
a sweeper mechanism configured to be moveable within the chamber of the DC-CVD reactor; and
a control mechanism configured to be operable outside the chamber of the DC-CVD reactor.

14. The direct current chemical vapor deposition (DC-CVD) reactor of claim 13, wherein the sweeper mechanism is vertically, laterally and rotationally moveable, through operation of the control mechanism.

15. The direct current chemical vapor deposition (DC-CVD) reactor of claim 13, wherein the sweeper mechanism is electrically insulated to both the grounded DC-CVD reactor chamber and output terminals of the DC power supply.

16. The direct current chemical vapor deposition (DC-CVD) reactor of claim 12, wherein the first electrode and second electrode have a circular cross-section with a diameter between 125 mm to 325 mm, and wherein the substrate holder has a deposition area of about 12,000 mm² to 75,000 mm².

17. The direct current chemical vapor deposition (DC-CVD) reactor of claim 12, wherein the first electrode is configured to be movable relative to the second electrode, such that an inter-electrode distance between the first and second electrodes can be varied from 40 mm to 100 mm.

18. The direct current chemical vapor deposition (DC-CVD) reactor of claim 12, wherein the DC power supply is either DC or pulsed DC that can operate and maintain within 5% of predetermined power levels (power-regulated) instead of the predetermined voltage (voltage-regulated) and current (current-regulated) levels.

19. The direct current chemical vapor deposition (DC-CVD) reactor of claim 12, wherein the DC power supply provides a voltage to the CVD reactor of about 900V to 1200V.

20. The direct current chemical vapor deposition (DC-CVD) reactor claim of 12, wherein temperature of the first electrode and second electrode are regulated via water-cooling, and the first and second electrodes comprise a flow meter and temperature sensor to regulate the flow rate and temperature of cooling water.

21. A DC-CVD diamond material, wherein the diamond material is a single crystal diamond (SCD) having a thickness of at least 1.0 mm.

22. A DC-CVD diamond material according to claim 21, wherein deposition process gases comprise more than 15 ppm but not more than 50 ppm of nitrogen.

23. A DC-CVD diamond material according to claim 21, wherein the diamond material exhibits a color grade of L, M to fancy yellow after HPHT treatment, if cut into a carat round brilliant gemstone.

24. A DC-CVD diamond material according to claim 21, wherein the diamond material exhibits a color grade of I, J, K after HPHT treatment, if cut into a carat round brilliant gemstone.
